(19) United States
(12) Patent Application Publication
(10) Pub. No.: US 2008/0111959 A1
(43) Pub. Date: May 15, 2008

(54) Trans-reflective liquid crystal display and manufacturing method thereof

(75) Inventors: Ta-Jung Su, Padeh City (TW); Yu-Wei Chang, Padeh City (TW); Ming-Sheng Chiang, Padeh City (TW)

Correspondence Address: BIRCH STEWART KOLASCH & BIRCH, PO BOX 747, FALLS CHURCH, VA, 22040-0747, US

(73) Assignee: CHUNGHWA PICTURE TUBES, LTD

(21) Appl. No.: 11/907,361

(22) Filed: Oct. 11, 2007

(30) Foreign Application Priority Data
Nov. 9, 2006 (TW) 95141579

(51) Int. Cl. H01L 21/02; G02F 1/1335

(52) U.S. Cl. 349/114; 438/30; 257/E21.536

(57) ABSTRACT

The structure of a trans-reflective liquid crystal display panel includes stacks in longitudinally and two areas in transversely, which are reflective area and transmissive area. A thin-film-transistor layer and a dielectric layer are formed on a substrate in sequential. For the transmissive area, a transparent conductive film, such as a pixel electrode, is formed. For the reflective area, a reflective film with multi-layer is formed on the dielectric layer and then the thin-film-transistor layer. After assembling, the trans-reflective liquid crystal display is complete. The materials of the reflective film with multi-layer and the dielectric layer are similar to have greater adhesion. Each layer of the reflective film with multi-layer includes two sublayers, the first reflective sublayer and the second reflective sublayer, which have the different refractive indexes. By modifying the temperature, pressure, gas flow and power of emitting in manufacturing process can make the refractive indexes of both layers.

### FIELD OF THE INVENTION

This invention relates to a trans-reflective liquid crystal display and the manufacturing method thereof, and more especially, to a reflective film with multi-layer in a trans-reflective liquid crystal display and its manufacturing method.

### BACKGROUND OF THE RELATED ART

A trans-reflective liquid crystal display (LCD) utilizes the incident light from front panel, and the light from a backlight module as its light source. In manufacturing, a reflective film is deposited on the partial substrate to reflect the incident light which is to provide a portion of light source for the LCD panel. Therefore, the other portion of light source is from the backlight module for the LCD panel.

FIG. 1 is a sectional diagram showing a conventional trans-reflective LCD with double cell gaps, and the LCD panel is divided into a transmissive area and a reflective area as shown in this longitudinal sectional view. The structure of the LCD panel is to form thin film transistors 200 on a substrate 100 and then to form a passivation layer (a dielectric layer) 300 over them.

After that, a transparent conductive film, such as a pixel electrode 400, is formed in the transmissive area. An organic insulating layer 500 is formed on the reflective area, and a reflective layer 600 is on the organic insulating layer 500. For the improvement in adhesion, an adhesive layer 410 is formed among the organic insulating layer 500, the passivation layer 300 and the transparent conductive film. Then, the organic insulating layer 500, a liquid crystal layer 700 and a color filter (CF) substrate 800 are stacked on sequentially to complete the LCD. As the result, the transparent conductive film is electrically connected to the TFTs by contact holes (CH).

For equaling the distance on the light paths of the incident light from front panel and the transmissive light from backlight module, the organic insulating layer 500 is formed to achieve the cell gap (d) in the reflective area is half of cell gap (2d) in the transmissive area. The ratio of the structures in FIG. 1 is the indications for better understanding this invention, and the thickness of the TFT can be disregarded actually. However, the reflective layer 600 and the organic insulating layer 500 are made of different materials, and the adhesive layer 410 cannot stick them well. So that the film peeling issue would be happened on the reflective layer 600, the organic insulating layer 500 and the transparent conductive film to reduce the quality of the trans-reflective LCD. Moreover, the intensity of the electric field in the reflective area is 2 times greater than that in the transmissive area, so that the response time on the reflective area is 4 times faster than that on the transmissive area.

FIG. 2 is a sectional diagram showing a conventional trans-reflective LCD with single cell gap, and it differs from the trans-reflective LCD with double cell gaps on that it does not need to form an organic insulating layer in the reflective area. The structures on its reflective area are a substrate 100, a thin film transistor layer 200, a dielectric layer 300, a transparent conductive film, such as a pixel electrode layer 400, an adhesive layer 410, a reflective layer 600, a liquid crystal layer 700 and a color filter substrate 800 in sequential, wherein the structures on its transmissive area are the substrate 100, a gate insulating layer 220, the dielectric layer 300, the transparent conductive film, such as a pixel electrode layer 400, the liquid crystal layer 700 and the color filter substrate 800 in sequential.

The ratio of the structures in FIG. 2 is the indication for better understanding this invention, and the thickness of the TFT can be disregarded actually, that is, the distance of the light path for the reflective light passing through liquid crystal from its reflective area is 2 times greater than that for the back light passing through liquid crystal from its transmissive area. As the result, there is a phase difference between the reflective light and backlight after passing through liquid crystal, and the light intensity of the backlight decays to one half when it emits out of the display due to the polarizing effect of the liquid crystal, that is, the utility ratio of the backlight is 50% only.

FIG. 3 is a sectional diagram showing a conventional trans-reflective LCD, which is disclosed in U.S. Pat. No. 6,765,637. A concavity-convexity layer 13a is formed in the display panel and covered by an insulating layer 7a with a lower refractive index, and a reflective film 8a covers the insulating layer 7a around the convex parts of the concavity-convexity layer 13a and reserves an opening in the centeral area as a transmission window 8d. The incident light from the front panel is reflected by the reflective film 8a to radiate outward, and the transmissive light passes the concavity-convexity layer 13a and the insulating layer 7a so that the light is focused on the transmission window 8d to radiate outward into liquid crystal layer. It is complex to form the concavity-convexity layer 13a and the transmission window 8d, and it is possible to have the peeling issue due to the material difference between the insulating layer 7a and the concavity-convexity layer 13a.

As the foregoing discussion, there are three subjects in manufacturing a trans-reflective LCD: (1) to increase the utility ratio of the light, (2) to simplify the manufacturing process, and (3) to enhance the adhesive strength of the reflective layer.

### SUMMARY OF THE INVENTION

For solving the problems mentioned above, an object of this invention is to provide a more efficient reflective film to increase the utility ratio of the light.

One object of this invention is to provide a more adhesive reflective film to enhance the adhesion, and to solve the peeling issue.

One object of this invention is to provide an integrated manufacturing process without depositing a metallic reflective layer to reduce the expense of a mask.

For achieving the objects mentioned above, an embodiment of this invention implements a trans-reflective liquid crystal display (trans-reflective LCD). The trans-reflective LCD includes a substrate, a plurality of thin film transistors (TFTs) formed on the substrate, a dielectric layer formed on the substrate over the thin transistors. The dielectric layer includes a plurality of contact holes to expose a portion of each TFT. The reflective film with multi-layer includes a plurality of openings and forms on the partial dielectric layer. Some openings expose the contact holes and others form the transmissive area. The rest area without openings will form the reflective area. Pixel electrodes are formed on the reflective film with multi-layer, and each pixel electrode is connected electrically to a TFT by the contact holes. Thus, a TFT array substrate is complete. After that, a liquid crystal layer is formed on the TFT array substrate, and then an opposite substrate, like a color substrate, is disposed on the liquid crystal layer to complete the trans-reflective liquid crystal display panel.

Each reflective film with multi-layer includes at least one unit consisting of a first reflective layer and a second reflective layer which have different refractive indexes, and the unit amount of the reflective film with multi-layer depends on the ratio of the refractive indexes. In general, the first refractive index is larger than the second one. The amount of the layers makes a net reflective index. The more the net reflective index approaches to 1, the higher the utility of the light is.

The material of the reflective film with multi-layer is similar to that of the dielectric layer. In general, the material is SiN_{y}, SiOₓ, SiOₓN_{y} or the combination thereof. When the x and y are different (the ratio of Silicon, Oxygen and Nitrogen is different), the refractive indexes will be different. Therefore, the net reflective index may approach to 1 by modifying the values of x or y and setting the amount of the layers. And, the adhesion between the reflective film with multi-layer and the dielectric layer will be enhanced due to the similar materials. Moreover, the reflective film with multi-layer and the dielectric layer can be integrated into a process.

For achieving the objects mentioned above, a manufacturing method of a trans-reflective liquid crystal display according to an embodiment of this invention is provided. The manufacturing method includes providing a bare TFT array substrate, forming a dielectric layer on the bare TFT array substrate, forming a reflective film with multi-layer on the dielectric layer, forming a photo-resist layer on the reflective film with multi-layer, exposing with a mask and developing. The mask includes a transparent region, a semi-transparent region and an opaque region to transfer a given pattern to the photo-resist layer after developing. The portion corresponding to the transparent region of the mask is removed by etching to expose the devices of the TFT array with contact holes. Next, an ashing step takes off the photo-resistance corresponding to the semi-transparent region of the mask. The another etching step is employed on the reflective film with multi-layer to expose the dielectric layer corresponding to the semi-transparent region of the mask. After the residual photo-resist layer is stripped away to form the pixel electrode, and then the TFT array substrate is complete. Continuously, an assembling process will complete the LCD panel. The first step of the assembling process is to set an opposite substrate, like a color filter substrate and then to inject the liquid crystal into the space between the substrates.

The steps of forming the dielectric layer and forming the reflective film with multi-layer may be merged to a single process when taking similar materials used into consideration. The single process may be the plasma enhanced chemical vapor deposition (PECVD), the physical vapor deposition (PVD) or the evaporation. What is considered in the single process is to form the different refractive indexes of the first and the second reflective layers in each reflective film with multi-layer by modifying temperature, pressure, gas flow or power.

The mask employed in the exposing step includes a full-transparent region, a semi-transparent region and an opaque region. After developing step, on one hand, the photo-resist layer corresponding to the full-transparent region has been removed to expose the reflective film with multi-layer. On the other hand, the photo-resist layer corresponding to the semi-transparent region is partially removed to leave about ⅓ to ½ thickness of the opaque region. The first etching step will form the contact holes corresponding to the full-transparent region of the mask. After the ashing step, the photo-resist layer corresponding to the semi-transparent region is taken off. The second etching step will remove reflective film with the multi-layer corresponding to the semi-transparent region to form the transmissive area. The rest area is the reflective area. When a dry etching is employed, the first etching, ashing and the second etching can be finished in a chamber to avoid repeating the complicated procedures such as vent and vacuum procedures.

As shown above, the steps of etching, ashing and depositing for the reflective film with multi-layer and the dielectric layer can be integrated into one process respectively, and the transmissive area and reflective area can be formed, and the trans-reflective LCD will be complete.

### BRIEF DESCRIPTION OF THE DRAWINGS

FIG. 1 is a sectional diagram of a trans-reflective liquid crystal display with a double-cell-gap according to a prior art.

FIG. 2 is a sectional diagram of a trans-reflective liquid crystal display with a single-cell-gap according to a prior art.

FIG. 3 is a sectional diagram of another trans-reflective liquid crystal display according to a prior art.

FIG. 4 is a sectional diagram of a multi-layer dielectric layer of a trans-reflective liquid crystal display according to an embodiment of this invention.

FIG. 5 is a sectional diagram of a trans-reflective liquid crystal display according to an embodiment of this invention.

FIG. 6A, 6B, 6C, 6D, 6E, 6F, 6G and 6H are the sectional diagrams of a trans-reflective liquid crystal display in different phases of the manufacturing process according to an embodiment of this invention.

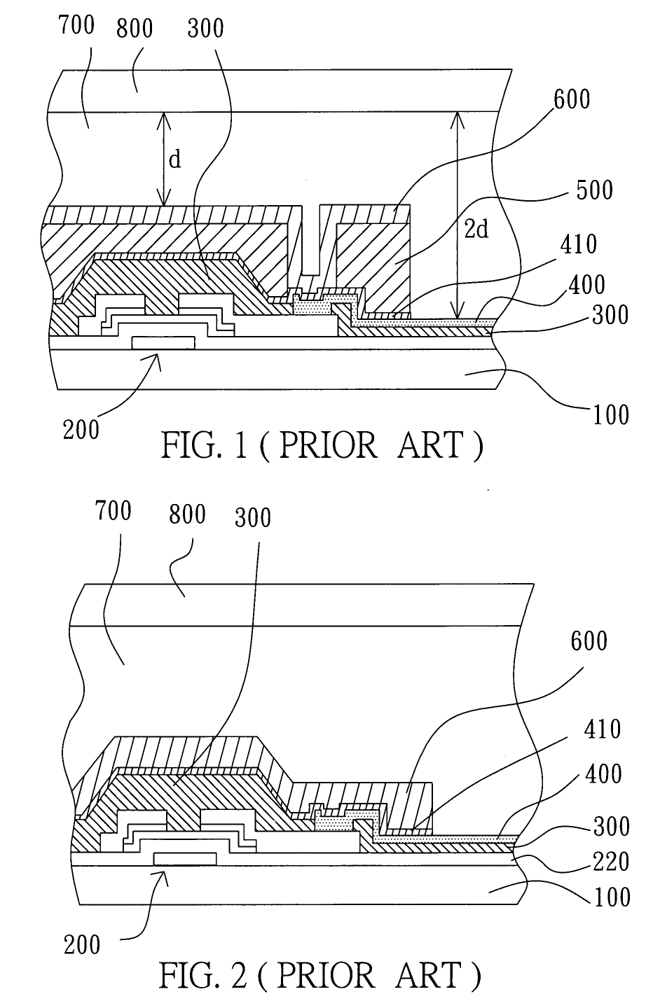

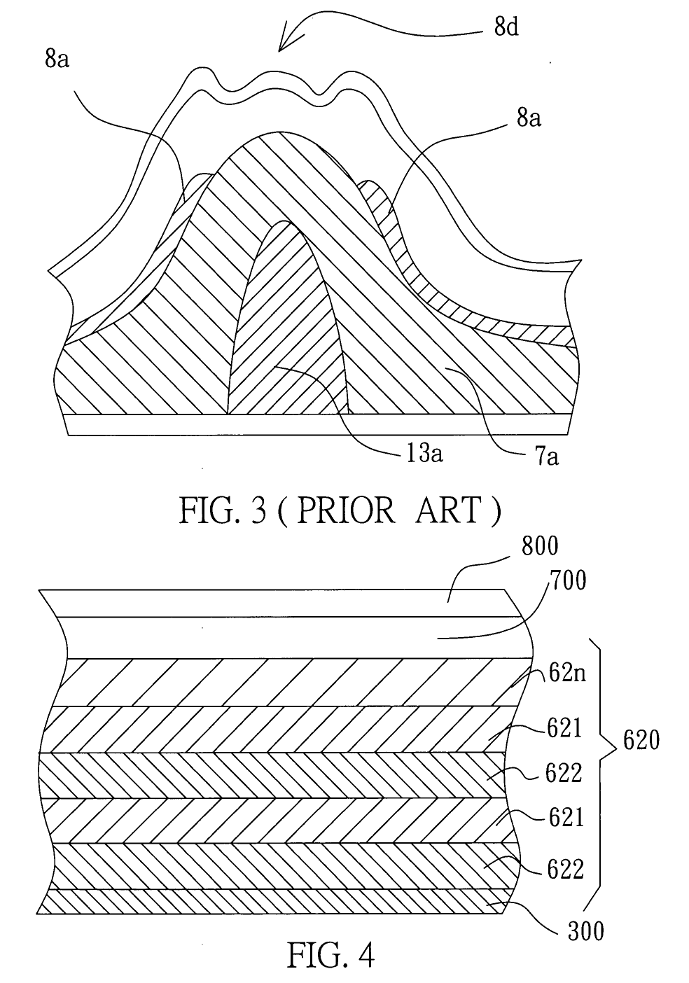

### DETAILED DESCRIPTION OF THE INVENTION

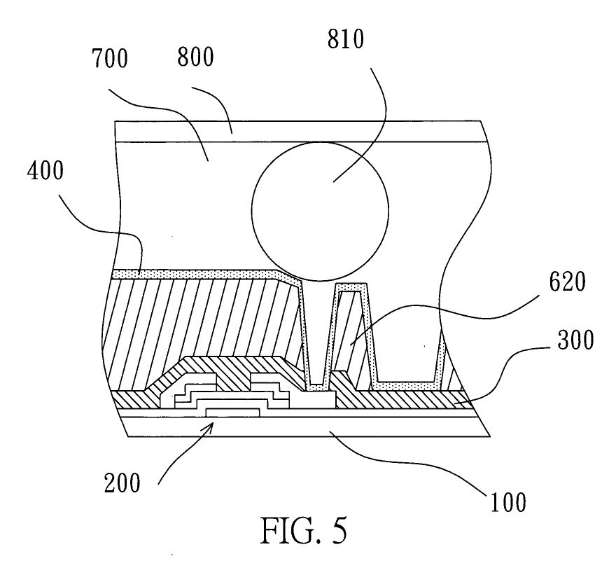

FIG. 4 shows a sectional view of the reflective area of a trans-reflective LCD according to an embodiment of this invention. A reflective film with multi-layer 620 is stacked on a dielectric layer 300, and each reflective film with multi-layer 620 includes at least one unit consisting of a first reflective layer 621 and a second reflective layer 622 which have different refractive indexes. For better understanding this invention, as shown in FIG. 4, a reflective layer 62n represents the non-physical structure of the reflective film with multi-layer, and the sequential stacked layers represent a liquid crystal layer 700 and a color filter substrate 800.

The reflective film with multi-layer 620 and the dielectric layer 300 are made of the similar materials, such as the silicon nitride SiN_{y}, the silicon oxide SiOₓ, silicon nitro oxide SiOₓN_{y} or their combination. When x and y are different (it means the ratio of the Si, O and N be different), the refractive index is different, that is, the first reflective layer 621 and the second reflective layer 622 of the reflective film with multi-layer 620 have different refractive indexes, and it varies according to the formula:

R={[(nₐ/nₛ)(n₂/n₁)^{2N}31 1]/[(nₐ/nₛ)(n₂/n₁)^{2N}+1]}², where R is the net reflective index, nₐ is the air refractive index, nₛ is the dielectric refractive index of the dielectric layer, n₂ is the refractive index of the second reflective layer in one unit of the reflective film with multi-layer, n₁ is the refractive index of the first reflective layer of the unit of the reflective film with multi-layer, and N is the unit amount of the reflective film with multi-layer.

For better understanding this invention, a simulation is calculated to show relationship of the amount of the layers, the net reflective index and the thickness of the reflective film with multi-layer under the following assumptions, wherein nₐ=1, nₛ=1.52, n₁=1.8, n₂=1.6, and the thickness of the first reflective layer=76.39 nanometer(nm) and the thickness of the second reflective layer=85.94 nanometer(nm). This is, the thickness of each unit of the reflective film with multi-layer=0.162 micrometer(μm). The relationship is represented as following table:

| layers | net reflective index | thickness(μm) |
|---|---|---|
| 1 | 0.099822 | 0.162 |
| 2 | 0.625023 | 0.325 |
| 3 | 0.852083 | 0.487 |
| 4 | 0.946754 | 0.649 |
| 20 | 1.00000 | 3.274 |

As shown in the above table, for a trans-reflective LCD with double cell gaps, it can replace the structure which is made of an organic insulating layer and a reflective layer in prior arts by forming 20-layer reflective film, and for a trans-reflective LCD with single cell gap, it can replace the structure which is made of a reflective layer in prior arts by forming 4-layer reflective film for enhancing the adhesion. Moreover, the net reflective index of the reflective film with multi-layer is almost equal to 1, this is, the whole incident light is almost reflected into liquid crystal, so the utility ratio of the reflective light is very high.

FIG. 5 is a sectional diagram showing a trans-reflective LCD according to an embodiment of this invention. For better understanding this invention, FIG. 5 shows the structure of the trans-reflective LCD for indicating the thickness ratio of various layers of the LCD. A TFT 200 is formed on a substrate 100 and covered by a dielectric layer 300, wherein the dielectric layer 300 includes a plurality of contact holes (CH) to expose the TFT 200. A reflective film with multi-layer 620 is formed on the dielectric layer 300 continuously. The reflective film with multi-layer 620 includes a plurality of openings. Some openings expose the contact holes and others expose a portion of the dielectric layer to form the transmissive area. The rest region without openings forms the reflective area. Sequentially, a transparent conductive film, such as a pixel electrode 400, is formed on the reflective film with multi-layer 620 to complete the TFT array substrate, wherein the transparent conductive film is made of ITO or IZO etc. The pixel electrode 400 is electrically connected to a TFT 200 by one of those contact holes. Finally, a liquid crystal layer 700 and color filter (CF) substrate 800 are formed continuously, and spacers 810 are employed to support the space of the liquid crystal layer 700.

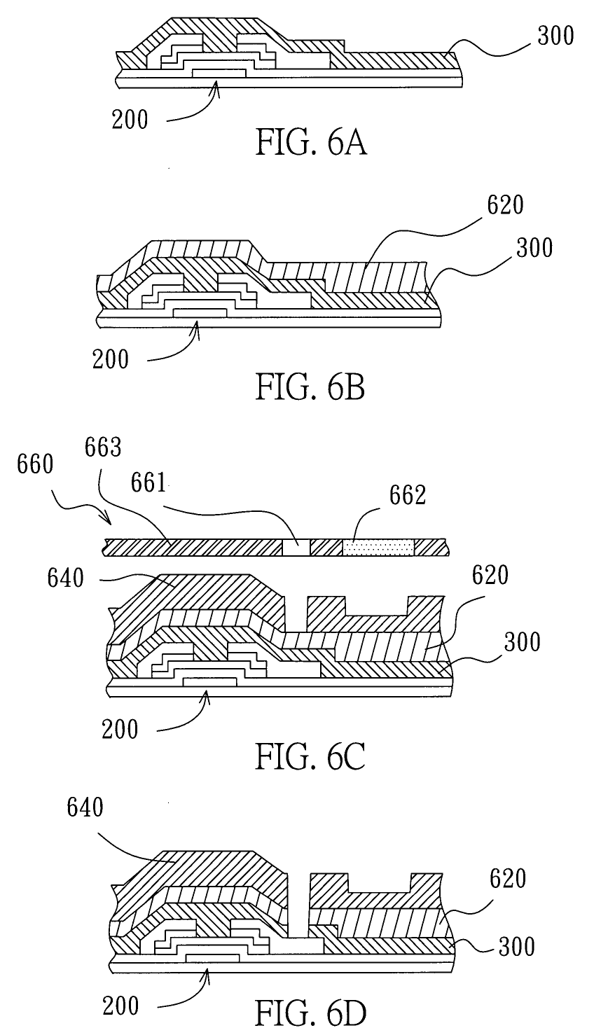

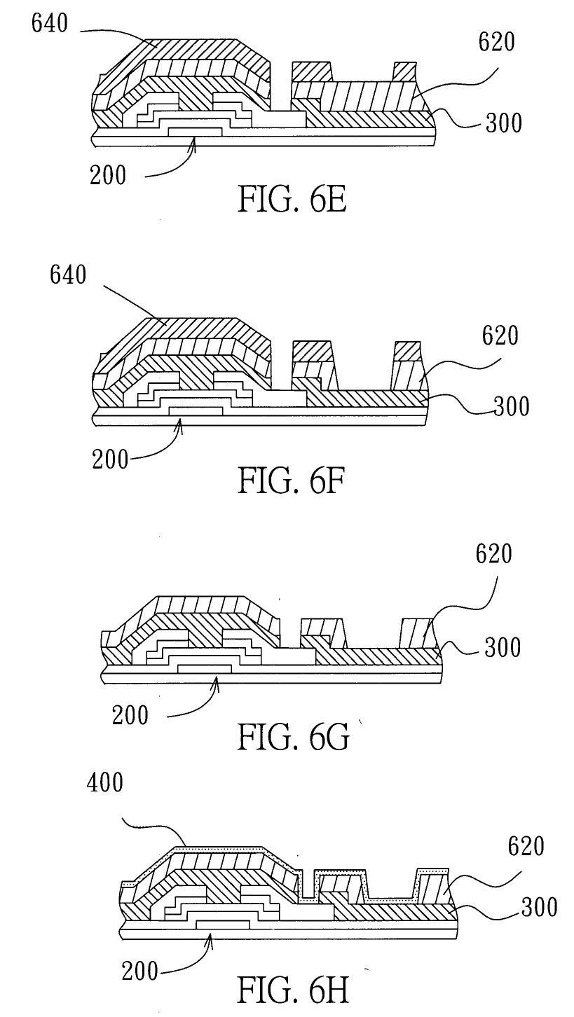

FIG. 6A˜6H show the sectional diagrams of a trans-reflective LCD in various manufacturing procedures according to an embodiment of this invention to explain the forming process of the reflective film with multi-layer, contact holes of the reflective area and the transmissive area.

FIG. 6A shows that a dielectric layer 300 is deposited on a substrate to cover TFTs 200 on the substrate.

FIG. 6B shows that a reflective film with multi-layer 620 is deposited on the dielectric layer 300.

FIG. 6C shows that a photo-resist layer 640 is formed, exposed through a full-transparent region 661 and a semi-transparent region 662 of a mask 660 and developed to transfer a given pattern to the photo-resist layer 640. Corresponding to the semi-transparent region 662, the thickness of the photo-resist layer 640 is about equal to ⅓ to ½ thickness of an opaque region 663 of the mask 660. Corresponding to the full-transparent region 661, the photo-resist layer 640 is removed, and the reflective film with multi-layer 620 is exposed.

FIG. 6D shows an etching step. The first etching step will form contact holes to expose the TFT 200.

FIG. 6E shows an ashing step. Corresponding to the semi-transparent region 662 of the mask 660, the photo-resist layer 640 is removed. Corresponding to the opaque region 663, the photo-resist layer 640 is pared to ½˜⅔ time of that of the original thickness.

FIG. 6F shows an etching step. The second etching step will form the transmissive area. The portion of the reflective film with multi-layer 620 uncovered by the photo-resist layer 640 will be removed to expose the dielectric layer 300.

FIG. 6G shows a striping photo-resist layer step. The photo-resist layer 640 will be taken off. The portion covered by the reflective film with multi-layer 620 will form the reflective area. The portion exposing the dielectric layer 300 will form the transmissive area.

FIG. 6H shows a depositing film step. A transparent conductive film, such as a pixel electrode 400, is formed. The transparent conductive film, such as the pixel electrode 400, is electrically connected to the TFT 200 through the contact hole.

Finally, the assembling process is performed. After assembling a color filter substrate 800 and injecting the liquid crystal to form the liquid crystal layer 700, the trans-reflective LCD is complete, as shown in FIG. 5.

Usually, the plasma enhanced chemical vapor deposition (PECVD), the physical vapor deposition (PVD) or the evaporation are employed in the step of forming the dielectric layer 300 as shown in FIG. 6A, and the step of forming the reflective film with multi-layer 620 as shown in FIG. 6B. If both layers are made of the similar materials, then these two procedures can be integrated. What is considered in the single process is to form the different refractive indexes of the first and the second reflective layers in each reflective film with multi-layer 620 by modifying temperature, pressure, gas flow or power.

When the dry etching technique are employed in the etching steps in FIG. 6D and FIG. 6F, these two etching steps and the ashing step in FIG. 6E can be integrated into one process to avoid the complicated procedures, such as to repeat the vent and vacuum procedures.

Although the present invention has been explained in relation to its preferred embodiment, it is to be understood that other modifications and variation can be made without departing the spirit and scope of the invention as claimed.

What is claimed is:

1. A trans-reflective liquid crystal display panel, comprising:
a thin film transistor array substrate, comprising:
a substrate;
a plurality of transistors disposed on the substrate;
a dielectric layer disposed on the substrate to cover the transistors, wherein the dielectric layer includes a plurality of contact holes to expose a portion of each transistor;
a reflective film with multi-layer disposed on the dielectric layer, wherein the reflective film with multi-layer includes a plurality of openings, and some of the openings expose the contact holes, and the other openings expose a portion of the dielectric layer; and
a plurality of pixel electrodes disposed on the reflective film with multi-layer to cover the openings and another portion of the dielectric layer, wherein the pixel electrodes are electrically connected to the transistors by the contact holes;
an opposite substrate disposed opposite on the thin film transistor array substrate; and
a liquid crystal layer disposed between the thin film transistor array substrate and the opposite substrate.

2. A trans-reflective liquid crystal display panel according to claim 1, wherein each reflective film with multi-layer comprises at least one unit consisting of a first reflective layer and a second reflective layer with two different refractive indexes.

3. A trans-reflective liquid crystal display panel according to claim 2, wherein the reflective film with multi-layer is made of silicon nitride, silicon oxide, silicon nitro-oxide or combination thereof.

4. A trans-reflective liquid crystal display panel according to claim 3, wherein each of the reflective film with multi-layer is to modify the different ratio of nitrogen, oxygen and silicon to form the different refractive indexes of the first reflective layer and the second reflective layer.

5. A trans-reflective liquid crystal display panel according to claim 2, wherein a refractive index of the first reflective layer is larger than that of the second reflective layer.

6. A trans-reflective liquid crystal display panel according to claim 2, wherein a unit amount of the reflective film with multi-layer depends on the ratio of two refractive indexes of the first reflective layer and the second reflective layer.

7. A trans-reflective liquid crystal display panel according to claim 1, wherein the trans-reflective liquid crystal display panel is a trans-reflective liquid crystal display panel with single cell gap.

8. A trans-reflective liquid crystal display panel according to claim 1, wherein the trans-reflective liquid crystal display panel is a trans-reflective liquid crystal display panel with double cell gaps.

9. A method of manufacturing a trans-reflective liquid crystal display panel, comprising:
providing a thin film transistor array substrate;
forming a dielectric layer on the thin film transistor array substrate;
forming a reflective film with multi-layer on the dielectric layer;
forming a photo-resist layer on the reflective film with multi-layer
exposing and developing the photo-resist layer to form a given pattern under a mask, which includes a full-transparent region, a semi-transparent region and an opaque region;
etching portion of the reflective film with multi-layer and the dielectric layer, corresponding to the full-transparent region of the mask, to the thickness of the thin film transistor array substrate to form contact holes
ashing portion of the photo-resist layer, corresponding to the semi-transparent region of the mask, to expose the reflective film with multi-layer
etching the exposed portion of the reflective film with multi-layer to the thickness of the dielectric layer;
removing the photo-resist layer;
forming a pixel electrode to cover the thin film transistor array substrate; and
combining a color filter substrate opposite on the thin film transistor array substrate and injecting liquid crystal between the color filter substrate and the thin film transistor array substrate.

10. A method of manufacturing a trans-reflective liquid crystal display panel according to claim 9, wherein the step of forming the dielectric layer comprises plasma enhanced chemical vapor deposition, physical vapor deposition or evaporation.

11. A method of manufacturing a trans-reflective liquid crystal display panel according to claim 9, wherein the step of forming the reflective film with multi-layer modifies its refractive index by controlling the temperature, pressure, gas flow and power.

12. A method of manufacturing a trans-reflective liquid crystal display panel according to claim 9, wherein those steps of forming the dielectric layer and the reflective film with multi-layer are integrated into a process.

13. A method of manufacturing a trans-reflective liquid crystal display panel according to claim 9, wherein the step of exposing and developing the photo-resist layer removes portion of the photo-resist layer corresponding to the full-transparent region to expose the reflective film with multi-layer, and pares off portion of the photo-resist layer to range from ⅓ to ½ time thickness of the photo-resist layer corresponding to the opaque region.

14. A method of manufacturing a trans-reflective liquid crystal display panel according to claim 9, wherein the step of etching is to utilize a dry etching technique.

15. A method of manufacturing a trans-reflective liquid crystal display panel according to claim 9, wherein the steps of those two etching and ashing are performed in the same vacuum chamber.
